(19) United States
(12) Patent Application Publication
(10) Pub. No.: US 2019/0189580 A1
(43) Pub. Date: Jun. 20, 2019

(54) THERMAL SHUNTS AND THERMAL MANAGEMENT IN MONOLITHIC MICROWAVE INTEGRATED CIRCUITS

(71) Applicant: DUET MICROELECTRONICS INC., Raritan, NJ (US)

(72) Inventors: Ali Badar Alamin Dow, Raritan, NJ (US); Robert Bayruns, Raritan, NJ (US); David Osika, Raritan, NJ (US); John Ueng-McHale, Raritan, NJ (US)

(73) Assignee: DUET MICROELECTRONICS INC., Raritan, NJ (US)

(21) Appl. No.: 16/216,264

(22) Filed: Dec. 11, 2018

Related U.S. Application Data
(60) Provisional application No. 62/599,090, filed on Dec. 15, 2017.

(51) Int. Cl. H01L 23/00; H01L 27/06; H01L 49/02; H01L 29/205; H01L 29/737; H01L 23/66; H01L 23/367; H01L 23/373; H01L 23/29; H01L 23/31; H01L 21/02; H01L 21/8252

(52) U.S. Cl. CPC H01L 24/14; H01L 2224/14519; H01L 28/20; H01L 29/205; H01L 29/7371; H01L 23/66; H01L 23/367; H01L 23/3736; H01L 23/291; H01L 23/3171; H01L 24/13; H01L 21/02175; H01L 21/02266; H01L 21/8252; H01L 2223/6683; H01L 2224/13144; H01L 27/0658

(57) ABSTRACT

A method for fabricating an electronic device includes fabricating a plurality of electronic components on a substrate; fabricating a plurality of posts on the plurality of electronic components; depositing filling material between the plurality of posts; and depositing a plurality of top layers, with each top layer disposed on a respective post, thereby fabricating the electronic device. Each top layer is composed of a metal. The step of fabricating the posts includes: fabricating the posts to have identical heights above the substrate. Each post is thermally-conductive, and may be composed of gold. The filling material is composed of MgO, which may be electron beam evaporated to be disposed between the posts. The step of depositing the filling material includes: controlling a thickness of the MgO being deposited by controlling an evaporation rate of the MgO.

### CROSS-REFERENCE TO RELATED APPLICATION

This application claims priority to U.S. Provisional Application No. 62/599,090, filed on Dec. 15, 2017, which is incorporated by reference in its entirety.

### FIELD OF INVENTION

The present invention relates to integrated circuit fabrication, more specifically to the manufacture of monolithic microwave integrated circuits with improved thermal management.

### BACKGROUND OF THE INVENTION

The increased demand for mobile communications devices especially for cellular telephones and personal digital assistant applications calls for high power-added efficiency (PAE) for longer battery life. Transmitting amplifiers in monolithic microwave integrated circuits (MMIC) employ many heterojunction bipolar transistors (HBT) where HBT technology can provide high power densities across small areas. MMICs employ different types of transistors such as the indium phosphide double-heterojunction bipolar transistor (InP-DHBT).

MMICs fabricated on indium phosphide (InP) or gallium arsenide (GaAs) wafers use multiple ternary or quaternary epitaxial structures such as aluminum gallium arsenide (AlGaAs) and indium gallium phosphide (InGaP), which can be deposited on a wafer using metalorganic chemical vapor deposition (MOCVD) or molecular beam epitaxy (MBE) deposition techniques. Multiple semiconductor processing steps are applied in manufacturing MMICs.

InP-DHBT is commonly used in high-speed applications for which they are biased with high current densities. Biasing the InP-DHBT results in heat generation, including within the collector region where the energetic electrons are subject to scattering effect. The resulting temperature rise depends on the thermal resistance (Rₜₕ), applied power, device geometry, and layer structure where the conduction band difference between the base and subcollector is about the voltage between the emitter and the collector (VCE) under normal operation of the InP-DHBT.

The generated heat becomes a critical issue for optimal performance of a MMIC. One major challenge for compound semiconductors based HBT technology is the heat spreading which increases the self-heating effect, resulting in an unstable operation of the entire MMIC. Generally, MMICs exhibit the best performance at lower temperature operation where a significant amount of the generated heat is spread away from the active regions of the transistors. Typically, hotter InP-DHBT regions decrease the device performance.

In addition, an InP-DHBT generates heat in the collector depletion region where energetic electrons undergo scattering resulting in a thermally driven failure, thus limiting the current density flowing to the device. Furthermore, the enhanced scattering prolongs the electron transit time in the collector region and hence reduces the current gain cutoff frequency. Thus, heat spreading from the InP-DHBT continues to be a major challenge in obtaining and maintaining high-speed performance, especially when operating a MMIC at high temperatures.

The application of an electrical potential on the transistor in the MMIC results in a significant amount of generated heat, especially at the interface region between the base and the emitter. As the junction temperature rises, a controlled optimal base-emitter voltage (VBE) is required to control the collector current. Furthermore, the required VBE adds a self-heating effect and therefore, it is required that the VBE is to be adjusted for an optimal collector current and prevent any thermal instability that limits the normal operation of the InP-DHBT.

In addition to the requirement of reduced battery power, a small high-speed MMIC and other circuitry are also required to reduce the size of cellular phones and maintain an adequate transmitting power level for clear communication signals. However, small-size MMIC devices generate high power densities, and hence higher temperature regions are generated. Thus, heat removal from the MMIC devices is required for stable operation and long-term reliability.

For proper functionality of the MMIC devices, the fingers of the emitters, base, and collectors are connected for good electrical and thermal performance such that the heat is removed by conduction or convection heat transfer. Thick gold (Au) via posts acting as thermal shunts are commonly used to connect the emitter, the collector, and the base to the top metal layer of the MMIC. Benzocyclobutene (BCB) is employed to fill in the gaps between the thick gold posts and multi-emitter finger configurations are considered for better thermal coupling. Furthermore, the inherent geometrical discontinuity of the emitter's physical dimensions and multi-finger configuration results in an inhomogeneous thermal distribution, especially in the emitter-base junction region. This results in additional heat in the region, which may reduce the transconductance of the device.

The use of Au posts as thermal shunts to dissipate joule heat in HBT devices has some limitations related to material and technology issues. The manufacturability of large and thicker metal post shunts for improved HBT thermal characteristics is limited by the properties of the thin film material, which is used to fill in the gaps between the posts. In addition, reproducibility in a large-scale manufacturing process is difficult with existing manufacturing approaches.

As mentioned above, the existing manufacturing methods use thick BCB as a filling material between the metal posts when linking various components in the MMIC to the top metal layer. Due to its low thermal conductivity of about 0.3 W/mK at room temperature, BCB limits the heat spreading to the upper metal level of the MMIC. However, because BCB and other common filling materials such as polyimide have very low thermal conductivity, they are not capable of effectively spreading the heat from the hot regions.

More details on the effects of heat spreading can be found in, for example, “Simulation of Thermally Shunted Multiple-Emitter-Finger AlGaAs/GaAs Heterojunction Bipolar Transistors Using A Finite Element Code”, Computational Mechanics, 1995, pages 610-615; and “Very High Power Density CW Operation Of GaAs/AlGaAs Microwave HBTs”, IEEE Electronic Device Letters, Vol., 14, No. 10, October 1993, pages 493-495, which are incorporated by reference.

The existing manufacturing methods using BCB pose other problems as well. The BCB is deposited by spin coating to the desired layer. Fine features defined with BCB and other polymers require a dry etch step using inductively coupled plasma reactive ion etch (ICP-RIE) for thickness uniformity and to secure a clean access to the top surface of the metal posts. Thus, ICP-RIE is a single wafer based process, which adds manufacturing cost and process time.

For applications that require a top thick metal layer, the BCB-based process can also suffer reliability problems. For example, process conditions must be controlled such that no air is trapped during the resist coat because trapped air may expand and propagate through the entire resist layer, especially during the soft bake.

Various other materials, methods of deposition, and structures have been devised to address some of these issues. For example, U.S. Pat. No. 8,143,654 discloses a thin diamond layer deposited by chemical vapor deposition and U.S. Pat. No. 7,919,855 discloses a boron phosphide layer deposited by chemical vapor deposition. However, those structures are very thick, and are expensive and time-consuming to manufacture.

Therefore, a need exists for a process for manufacturing MMICs and other semiconductor devices that maintains good compatibility with all other process steps yet simplifies the process and accelerates heat spreading from hot regions in the device.

### SUMMARY OF THE INVENTION

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

In one embodiment, the present invention is a method for fabricating an electronic device comprising: fabricating a plurality of electronic components on a substrate; fabricating a plurality of posts on the plurality of electronic components; depositing filling material between the plurality of posts; and depositing a plurality of top layers, with each top layer disposed on a respective post, thereby fabricating the electronic device. Each top layer is composed of a metal. The step of fabricating the posts includes: fabricating the posts to have identical heights above the substrate. Each post is thermally-conductive, and may be composed of gold. The filling material is composed of MgO, which may be electron beam evaporated to be disposed between the posts. The step of depositing the filling material includes: controlling a thickness of the MgO being deposited by controlling an evaporation rate of the MgO.

In another embodiment, the present invention is an electronic device fabricated by a method comprising: fabricating a plurality of electronic components on a substrate; fabricating a plurality of posts on the plurality of electronic components; depositing filling material between the plurality of posts; and depositing a plurality of top layers, with each top layer disposed on a respective post. Each top layer is composed of a metal. The step of fabricating the posts includes: fabricating the posts to have identical heights above the substrate. Each post is thermally-conductive, and may be composed of gold. The filling material is composed of MgO, which may be electron beam evaporated to be disposed between the posts. The step of depositing the filling material includes: controlling a thickness of the MgO being deposited by controlling an evaporation rate of the MgO.

In an alternative embodiment, the present invention is an electronic device comprising: a substrate; a plurality of electronic components disposed on the substrate; a plurality of posts disposed on the plurality of electronic components; and a filling material disposed between the plurality of posts. A plurality of top layers may be included, with each top layer disposed on a respective post. The posts have identical heights above the substrate. The filling material is composed of MgO.

### BRIEF DESCRIPTION OF THE SEVERAL VIEWS OF DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 a flow chart of the manufacturing process of the present invention.

FIG. 2 is a cross-sectional view of an example InP-DHBT-based MMIC prior to deposition and structuring of filling material.

FIG. 3 is the MMIC of FIG. 2 with a photoresist layer applied according to the manufacturing process of the present invention.

FIG. 4 is the MMIC of FIG. 3 with MgO deposited according to the manufacturing process of the present invention.

FIG. 5 is the MMIC of FIG. 4 with a second metal layer deposited according to the manufacturing process of the present invention.

FIG. 6 is a partial top view of the MMIC of FIG. 5.

FIG. 7 is an illustration of an MMIC used for simulation testing of the manufacturing process of the present invention.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION OF THE INVENTION

Certain terminology is used in the following description for convenience only and is not limiting. The article “a” is intended to include one or more items, and where only one item is intended the term “one” or similar language is used. Additionally, to assist in the description of the present invention, words such as top, bottom, side, upper, lower, front, rear, inner, outer, right and left are used to describe the accompanying figures. The terminology includes the words above specifically mentioned, derivatives thereof, and words of similar import.

The design and manufacturing process of MMICs with thick Au posts involves the choice of the right material and/or stack to fill the gaps between the Au posts. From a process point of view, the fabrication process for filling the gaps in between the posts must be at lower temperature range, i.e., less than 300° C., to avoid any degradation in the transistor performance especially after forming the main electrical contacts of the device. From a design perspective, the properties of the filler material are particularly important. For an MMIC that requires a relatively low operating temperature, high thermal conductivity is critical. Therefore, the filling material should meet all yield and reliability expectations. In addition, in high-frequency applications, InP-DHBTs are expected to generate high heat fluxes, e.g., greater than 2 mW/μm².

In view of the foregoing, the present invention details the manufacturing process for using MgO as a filling material instead of BCB. The present invention involves deposition and structuring of the MgO layer between Au posts. This is conducted after the fabrication of the electronic components on the substrate and before deposition and structuring of the top metal layer.

The present manufacturing approach is not limited to a specific semiconductor device and can be used in the production of any other semiconductor device including devices and circuits fabricated on InP substrates, GaAs substrates, silicon substrates, fused silica substrates, and pyrex glass wafers.

The present invention overcomes the challenges associated with the existing methods of manufacturing high-speed MMIC devices. Compared to the prior-art devices, the selected thin film material to fill in the gap between the metal posts area is chosen to have high thermal conductivity and very good integration compatibility with the other fabrication steps of the device.

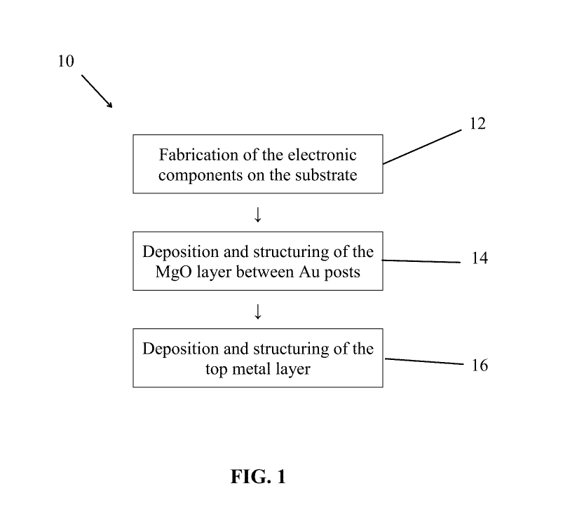

Referring to FIG. 1, the manufacturing process 10 begins by fabricating electronic components onto a substrate in step 12, as is known in the art. Next, magnesium oxide (MgO) is deposited and structured between the Au posts in step 14. Finally, a top metal layer is deposited and structured in step 16.

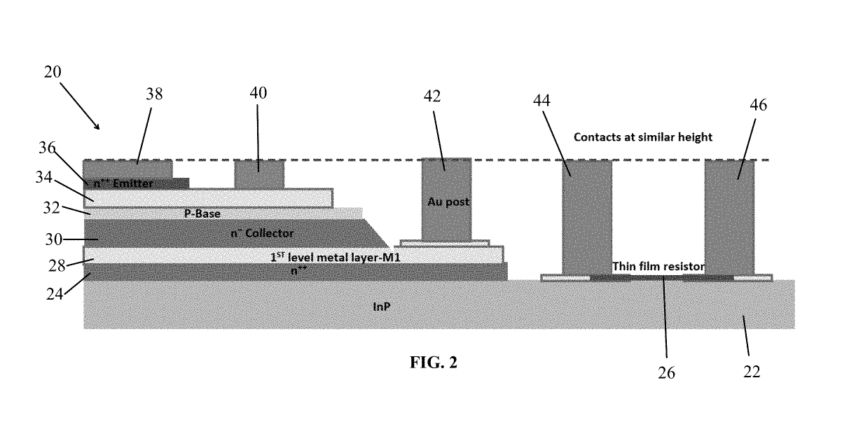

FIG. 2 shows a possible configuration of epitaxial layers for InP-DHBT based MMICs, which may include microstrip transmission lines, thin film resistors, and capacitors. In the structure 20 shown in FIG. 2, in an example embodiment of an MMIC, an InP substrate 22 has an n++ layer 24 and a thin film resistor 26 deposited thereupon. A first level metal layer M1 28 is then deposited on the n++ layer 24, and an n− collector 30, a p-base 32, an emitter layer 34, and an emitter cap as an n++ emitter 36 are subsequently deposited. A plurality of posts 38, 40, 42, 44, 46 are then selectively deposited on various components of the structure 20, with the posts 38-46 being thermally conductive and functioning as thermal shunts. In an example embodiment, the posts 38-46 are composed of gold (Au).

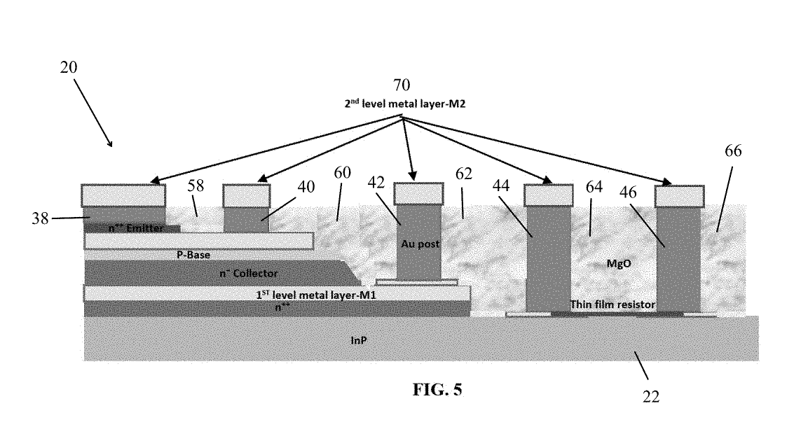

The Au posts 38-46 are fabricated to have similar or identical heights above the substrate 22, and so the Au posts 38-46 are used to equalize the height of the emitter, the base, and the collector, and to connect them to the next or top metal level, shown in FIG. 5. The production process for the MMIC shown in FIG. 2 uses multiple steps, which include but are not limited to photolithography, thin film deposition, metal lift off and etching.

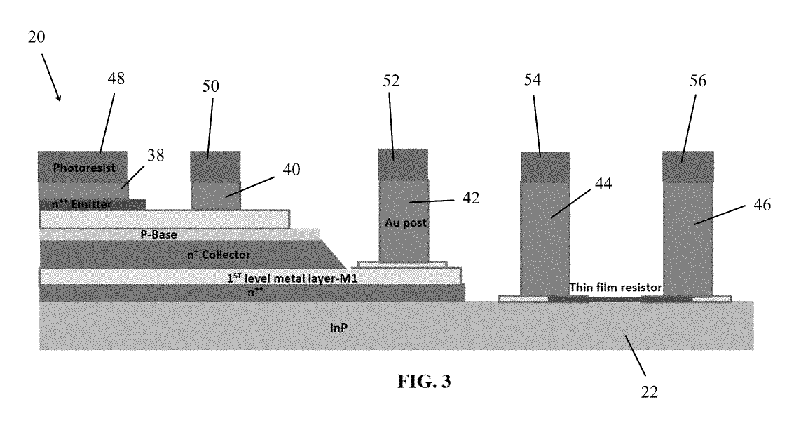

FIG. 3 shows the patterned lift off resist or negative resist layer, as photoresists 48, 50, 52, 54, 56, with openings on which the MgO will be deposited. As known in the prior art, the photoresist is a light-sensitive material used to form a patterned coating on a surface. Here, the negative photoresist is exposed to light, more specifically to electron beam, and becomes insoluble to the photoresist developer. The unexposed portion of the photoresist is dissolved by the photoresist developer. The negative photoresist could be, for example, an epoxy-based polymer such as SU-8 or an off-stoichiometry thiol-enes (OSTE) polymer.

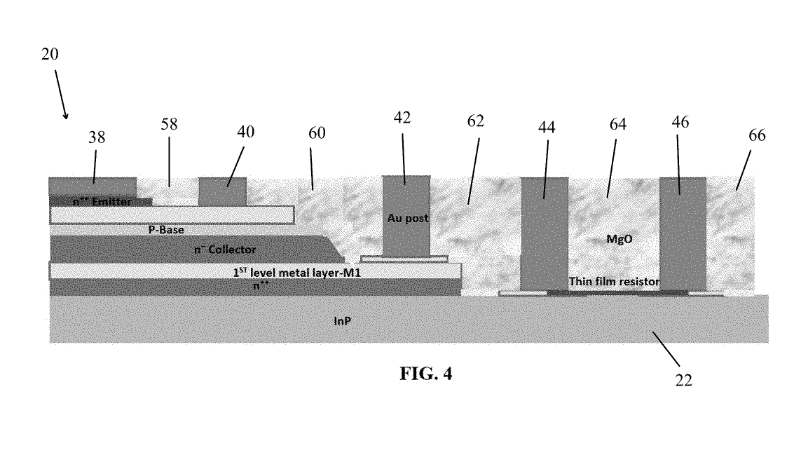

Referring to FIG. 4, the MgO layer, having portions 58, 60, 62, 64, 66 between the posts 38, 40, 42, 44, 46, respectively, is electron beam evaporated or otherwise-deposited to fill in the gaps between the Au posts 38-46. MgO is directly patterned using a lift off process where the InP substrate 22 is immersed in N-Methyl-2-pyrrolidone (NMP) based solution heated in the range of 80° C. to 100° C. to lift off the evaporated MgO, leaving MgO on the target openings. Unlike BCB and other polymers, the thickness of the layers 58-66 of the MgO can be controlled by the evaporation rate, and no ICP-RIE step is required which significantly reduces the cost and the required time in the manufacturing process of MMIC.

The present invention uses electron beam evaporated MgO as a filling material due to its good insulation properties, relatively high thermal conductivity of 35 W/mK, amorphous structure, high breakdown field of 12 MV/cm, low cost and compatibility with the entire manufacturing process of the MMIC. Electron beam evaporated MgO in the range of 80° C. to 100° C. is directly patterned using a lift off resist, which eliminates many steps in the manufacturing process.

The precise MgO thickness can be adjusted by the evaporation rate to accommodate any design requirements for the spacing between the Au posts 38-46, thickness of the top metal layers and Au posts 38-46, and evaporation at any angle. The process deposits the MgO with a controlled thickness, eliminating the need for dry etching to access the top surface of the posts.

The higher thermal conductivity of MgO (about 35 W/mK) enhances the heat spreading from the device. The evaporated MgO allows large and thick Au posts to further enhance heat dissipation from the device.

Referring to FIG. 5, the top second level metal layer M2 70 is deposited onto the posts 38-46, respectively, which is known in the back-end-of-line (BEOL) processing prior art. Generally, the top metal layer 70 is applied to the Au posts 38-46 to form the desired electrical circuits.

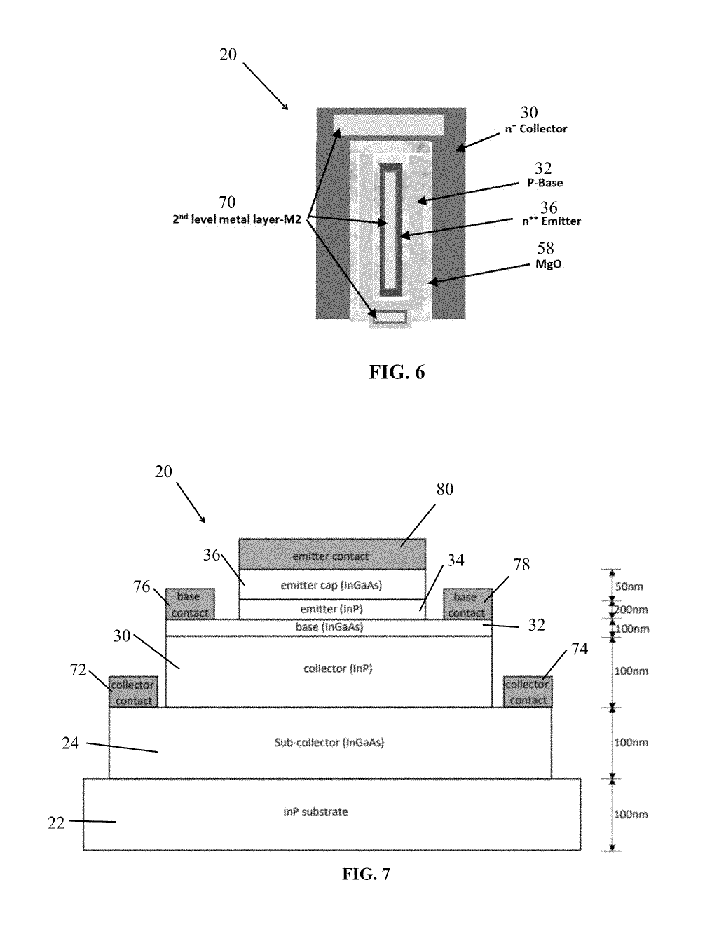

FIG. 6 illustrates a partial top view of the MMIC structure 20 in FIG. 5 after the completion of the top second metal layer 70.

FIG. 7 illustrates possible epitaxial layers and dimensions of the InP-DHBT, which were used to determine the temperature difference of using MgO instead of BCB. In an example embodiment, the structure 20 includes an InP substrate 22, an InGaAs sub-collector 24, an InP collector 30, an InGaAs base 32, an InP emitter 34, and an InGaAs emitter cap 36, with the top metal layer 70 forming collector contacts 72, 74, base contacts 76, 78, and an emitter contact 80. The structure 20 and its components were simulated using ATLAS™ from SILVACO INC., which is well known as an industry standard semiconductor device simulator. The simulation results exhibited a significant amount of heat spreading when BCB in the prior art is replaced with MgO. The maximum thermal conductivity was scaled by 50% or more from its maximum value.

TABLE 1

| | | Thermal | | |
|---|---|---|---|---|
| | Thermal Conductivity | Resistance | Temperature Rise | f_{T} |
| Material | (W/mK) | (K μm/W) | (K) | (GHz) |
| BCB | 0.15 | 57476 | 140.8162 | 91.5 |
| | 0.3 | 55435 | 135.81575 | 92.2 |
| MgO | 12 | 32537 | 79.7157 | 102 |
| | 35 | 22076 | 54.0862 | 107 |

Referring to Table 1, the cut-off frequency f_{T} increased by >10% when BCB in the prior art is replaced with MgO, even when assuming a thermal conductivity of 12 W/mK instead of 35 W/mK for the MgO. The thermal resistance is also reduced by at least 50% when using MgO as a filling material 58-66 between the Au posts 38-46. Improvement of the cut-off frequency f_{T} was also exhibited, which is very important for high speed and reliable MMIC devices.

The MgO process embodied in the present invention, which uses standard e-beam evaporation and lift-off, is compatible with the rest of the MMIC fabrication process and will eliminate some expensive and lengthy process steps such as photolithography and ICP-RIE. Furthermore, MgO offers better heat dissipation and the promise of more reliable operation versus the use of BCB.

The present invention may be embodied in other specific forms without departing from its spirit or essential characteristics. The described embodiments are to be considered in all respects only as illustrative and not restrictive. The scope of the invention will be, therefore, indicated by claims rather than by the foregoing description. All changes which come within the meaning and range of equivalency of the claims are to be embraced within their scope.

What is claimed is:

1. A method for fabricating an electronic device comprising:
fabricating a plurality of electronic components on a substrate;
fabricating a plurality of posts on the plurality of electronic components;
depositing filling material between the plurality of posts; and
depositing a plurality of top layers, with each top layer disposed on a respective post, thereby fabricating the electronic device.

2. The method of claim 1, wherein each top layer is composed of a metal.

3. The method of claim 1, wherein the step of fabricating the posts includes:
fabricating the posts to have identical heights above the substrate.

4. The method of claim 1, wherein each post is thermally-conductive.

5. The method of claim 4, wherein each post is composed of gold.

6. The method of claim 1, wherein the filling material is composed of MgO.

7. The method of claim 6, wherein the MgO is electron beam evaporated to be disposed between the posts.

8. The method of claim 7, wherein the step of depositing the filling material includes:
controlling a thickness of the MgO being deposited by controlling an evaporation rate of the MgO.

9. An electronic device fabricated by a method comprising:
fabricating a plurality of electronic components on a substrate;
fabricating a plurality of posts on the plurality of electronic components;
depositing filling material between the plurality of posts; and
depositing a plurality of top layers, with each top layer disposed on a respective post.

10. The method of claim 9, wherein each top layer is composed of a metal.

11. The method of claim 9, wherein the step of fabricating the posts includes:
fabricating the posts to have identical heights above the substrate.

12. The method of claim 9, wherein each post is thermally-conductive.

13. The method of claim 12, wherein each post is composed of gold.

14. The method of claim 9, wherein the filling material is composed of MgO.

15. The method of claim 14, wherein the MgO is electron beam evaporated to be disposed between the posts.

16. The method of claim 15, wherein the step of depositing the filling material includes:
controlling a thickness of the MgO being deposited by controlling an evaporation rate of the MgO.

17. An electronic device comprising:
a substrate;
a plurality of electronic components disposed on the substrate;
a plurality of posts disposed on the plurality of electronic components; and
a filling material disposed between the plurality of posts.

18. The electronic device of claim 17, further comprising.
a plurality of top layers, with each top layer disposed on a respective post.

19. The electronic device of claim 17, wherein the posts have identical heights above the substrate.

20. The electronic device of claim 17, wherein the filling material is composed of MgO.
